(19) United States
(12) Patent Application Publication
(10) Pub. No.: US 2025/0063818 A1
(43) Pub. Date: Feb. 20, 2025

(54) WIRING BODY AND DISPLAY DEVICE

(71) Applicant: TDK Corporation, Tokyo (JP)

(72) Inventors: Hiroshi SHINGAI, Tokyo (JP); Daisuke SONODA, Tokyo (JP); Toshiaki KASAI, Tokyo (JP); Tomoyuki GOI, Tokyo (JP); Yasumasa HARIHARA, Tokyo (JP)

(73) Assignee: TDK Corporation, Tokyo (JP)

(21) Appl. No.: 18/801,851

(22) Filed: Aug. 13, 2024

(30) Foreign Application Priority Data
Aug. 14, 2023 (JP) 2023-131907

(51) Int. Cl. H01L 27/12

(52) U.S. Cl. CPC H01L 27/124

(57) ABSTRACT

A wiring body includes a first resin layer having a first main surface and a second main surface and having a through hole passing from the first main surface to the second main surface, an electroconductive layer disposed in the through hole, and a first adhesive layer covering the first resin layer and the electroconductive layer from the first main surface side.

### CROSS-REFERENCE TO RELATED APPLICATION

This application claims priority to Japanese Patent Application No. 2023-131907 filed on Aug. 14, 2023, the entire contents of which are incorporated by reference herein.

### TECHNICAL FIELD

The present disclosure relates to a wiring body and a display device.

### BACKGROUND

A structure has been conventionally known in which a conductive mesh pattern with a substrate layer removed is mounted on a display device using a transparent adhesive layer (for example, Japanese Unexamined Patent Publication No. 2017-504094).

### SUMMARY

A wiring body according to one aspect of the present disclosure includes a first resin layer having a first main surface and a second main surface and having a through hole passing from the first main surface to the second main surface, an electroconductive layer disposed in the through hole, and a first adhesive layer covering the first resin layer and the electroconductive layer from the first main surface side.

A display device according to an aspect of the present disclosure includes the wiring body.

### BRIEF DESCRIPTION OF THE DRAWINGS

FIG. 1 is a plan view illustrating an electroconductive member including a wiring body according to an embodiment;

FIG. 2 is a cross-sectional view taken along the line II-II in FIG. 1;

FIG. 3 is a cross-sectional view illustrating an electroconductive member according to a modification;

FIG. 4 is a cross-sectional view illustrating a display device according to an embodiment;

FIG. 5 is a plan view of an antenna including a wiring body;

FIG. 6 is an enlarged cross-sectional view taken along the line VI-VI in FIG. 5;

FIG. 7 is an enlarged cross-sectional view illustrating a configuration in the vicinity of an end face of a first electroconductive line illustrated in FIG. 6;

FIG. 8 is a schematic cross-sectional view illustrating a method of manufacturing a wiring body; and

FIG. 9 is a schematic cross-sectional view illustrating a method of manufacturing a wiring body.

### DETAILED DESCRIPTION

Here, an electroconductive mesh pattern mounted on the display device is configured with a pattern having a very narrow line width in order to reduce the visibility. In a wiring body having such a configuration, since the substrate layer is removed, the shape of the mesh pattern may be deformed. On the other hand, providing a substrate layer for maintaining the shape of the mesh pattern presents a problem that the thickness of the wiring body increases.

In view of the above, an object of the present disclosure is to provide a wiring body whose thickness can be reduced with a shape of an electroconductive layer maintained, and a display device.

According to an aspect of the present disclosure, it is possible to provide a wiring body whose thickness can be reduced with a shape of an electroconductive layer maintained, and a display device.

Hereinafter, some embodiments of the present disclosure will be described in detail. However, the present disclosure is not limited to the following embodiments.

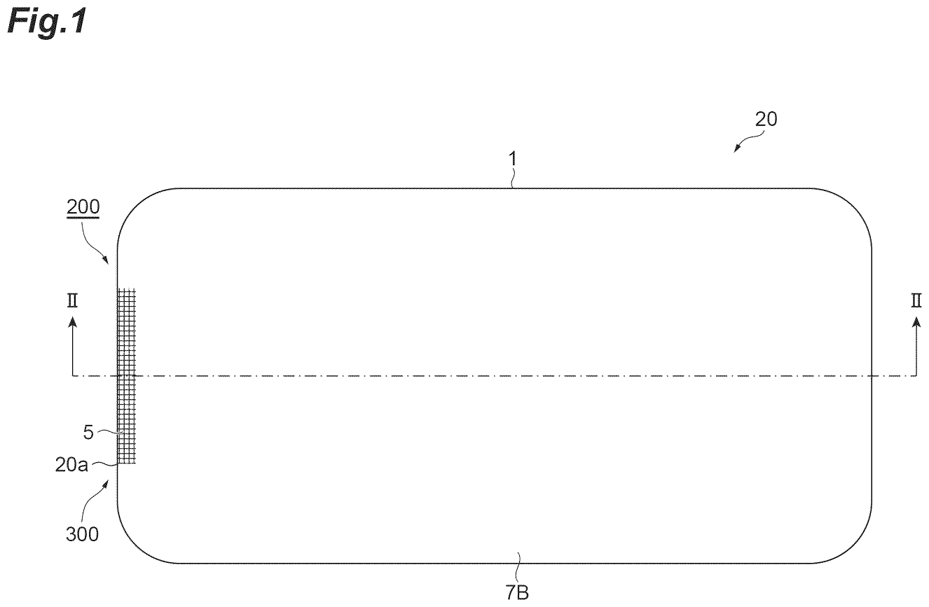

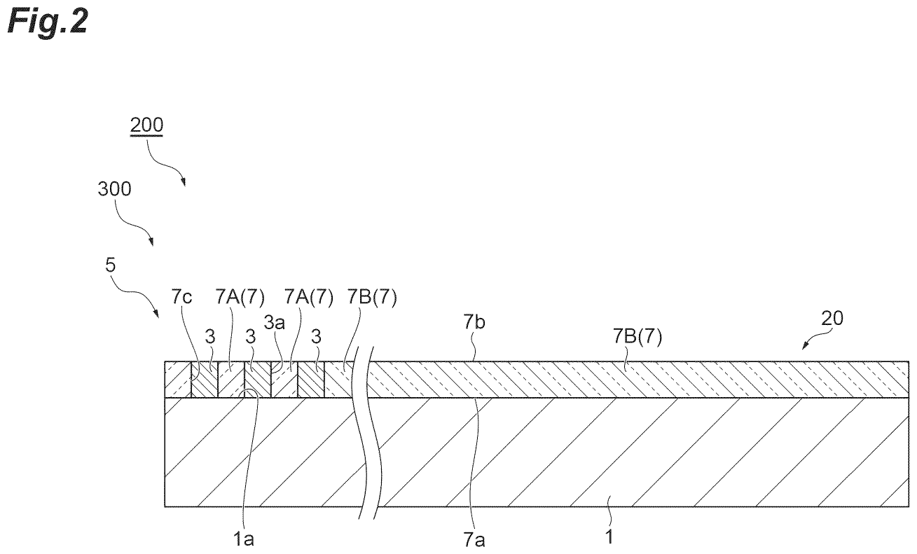

FIG. 1 is a plan view illustrating an electroconductive member 20 including a wiring body 200 according to an embodiment of the present disclosure, and FIG. 2 is a cross-sectional view taken along the line II-II in FIG. 1. The electroconductive member 20 includes an antenna 300, and the antenna 300 includes the wiring body 200. The electroconductive member 20 illustrated in FIGS. 1 and 2, that is, the wiring body 200, includes a first resin layer 7, an electroconductive layer 5, and a first adhesive layer 1. The first resin layer 7 has a first main surface 7a and a second main surface 7b. The first resin layer 7 has a through hole 7c that passes from the first main surface 7a to the second main surface 7b. The first resin layer 7 has an insulating resin portion 7A which is a region having the through hole 7c and a light transmissive resin layer 7B. The electroconductive layer 5 is disposed in the through hole 7c. The electroconductive layer 5 has a conductor portion 3 that extends in a direction along the main surfaces 7a and 7b and has a portion having a pattern including a plurality of openings 3a. The insulating resin portion 7A is configured to fill the openings 3a of the conductor portion 3. In FIG. 2, the electroconductive layer 5 is illustrated in a deformed manner, and the width of the conductor portion 3 is illustrated in an emphasized manner. The thickness of each layer is also illustrated in a deformed manner. Details of the thickness of each layer will be described later. In the example illustrated in FIG. 1, the electroconductive layer 5 is formed near one short side of the electroconductive member 20, but the position where the electroconductive layer 5 is formed is not particularly limited, and the electroconductive layer 5 may be formed near a long side. The first adhesive layer 1 covers the first resin layer 7 and the electroconductive layer 5 from the first main surface 7a side. The first adhesive layer 1 is a layer that exerts the adhesion to another member when the wiring body 200 is adhered to the other member on the first main surface 7a side. The first adhesive layer 1 is so disposed that a main surface 1a thereof is in contact with the first main surface 7a of the first resin layer 7. It is not essential that the first adhesive layer 1 covers the entire surfaces of the first resin layer 7 and the electroconductive layer 5 on the first main surface 7a side.

The first adhesive layer 1 has optical transparency to an extent required when the electroconductive member 20 is incorporated in a display device. Specifically, the total light transmittance of the first adhesive layer 1 may be 90 to 100%. The first adhesive layer 1 may have a haze of 0 to 5%.

The material of the first adhesive layer 1 may be, for example, acrylic, urethane, silicone, or the like. The thickness of the first adhesive layer 1 may be 50 to 250 μm. The dielectric constant of the first adhesive layer 1 may be 2.5 to 4.5@1 MHz.

The conductor portion 3 constituting the electroconductive layer 5 includes a part having a pattern including the openings 3a. The pattern including the openings 3a is a mesh-like pattern that is formed by a plurality of linear portions intersecting each other and includes the plurality of openings 3a regularly arranged. The conductor portion 3 having the mesh-like pattern can favorably function as, for example, a radiation conductor and a feed line of the antenna 300. The conductor portion 3 includes a planar pattern having no openings 3a. The conductor portion 3 having the planar pattern functions as a terminal and a ground pad portion described later. The configuration of the pattern of the conductor portion 3 in the electroconductive layer 5 will be detailed later.

The conductor portion 3 may contain metal. The conductor portion 3 may contain at least one metal selected from copper, nickel, cobalt, palladium, silver, gold, platinum, and tin, or may contain copper.

The conductor portion 3 may be metal plating formed by a plating method. The conductor portion 3 may further contain a nonmetallic element such as phosphorus within a range in which appropriate conductivity is maintained.

The conductor portion 3 may be a laminate including a plurality of layers. In addition, the conductor portion 3 may have a blackened layer as a surface layer portion on a side opposite to the first adhesive layer 1. The blackened layer can contribute to improvement in visibility of a display device in which the electroconductive member is incorporated. Here, the side opposite to the first adhesive layer 1 is the surface layer portion, but the first adhesive layer 1 side may be the surface 25 layer portion. In this case, the first adhesive layer 1 may have a blackened layer as the surface layer portion.

The insulating resin portion 7A is formed of a light transmissive resin and is provided so as to fill the openings 3a of the conductor portion 3, and the insulating resin portion 7A and the conductor portion 3 usually form a flat surface. The term “flat” as used herein also means that some unevenness (the electroconductive layer has a portion lower than the surface of the resin layer) is allowed. In other words, a state in which the outermost surfaces of the insulating resin portion 7A and the conductor portion 3 are not completely on the same plane is also allowed.

The light transmissive resin layer 7B is formed of a light transmissive resin. The total light transmittance of the light transmissive resin layer 7B may be 90 to 100%. The light transmissive resin layer 7B may have a haze of 0 to 5%.

The difference between the refractive index of the first adhesive layer 1 and the refractive index of the light transmissive resin layer 7B may be 0.1 or less. As a result, good visibility of a display image is more easily achieved. The refractive index (nd 25) of the light transmissive resin layer 7B may be, for example, 1.0 or more, and may be 1.7 or less, 1.6 or less, or 1.5 or less. The refractive index can be measured by a spectroscopic ellipsometer. In terms of uniformity of the optical path length, the conductor portion 3, the insulating resin portion 7A, and the light transmissive resin layer 7B may have substantially the same thickness.

The resin forming the insulating resin portion 7A and the light transmissive resin layer 7B may be a cured product of a curable resin composition (photocurable resin composition or thermosetting resin composition). The curable resin composition forming the insulating resin portion 7A and/or the light transmissive resin layer 7B includes a curable resin, and examples thereof include an acrylic resin, an amino resin, a cyanate resin, an isocyanate resin, a polyimide resin, an epoxy resin, an oxetane resin, a polyester, an allyl resin, a phenolic resin, a benzoxazine resin, a xylene resin, a ketone resin, a furan resin, a COPNA resin, a silicon resin, a dicyclopentadiene resin, a benzocyclobutene resin, an episulfide resin, a thiol-ene resin, a polyazomethine resin, a polyvinyl benzyl ether compound, acenaphthylene, and an ultraviolet curable resin containing a functional group that causes a polymerization reaction with ultraviolet rays such as an unsaturated double bond, a cyclic ether, and a vinyl ether.

The resin forming the insulating resin portion 7A and the resin forming the light transmissive resin layer 7B may be the same. Since the insulating resin portion 7A and the light transmissive resin layer 7B formed of the same resin have the same refractive index, the uniformity of the optical path length transmitted through the electroconductive member 20 can be further improved. In a case where the resin forming the insulating resin portion 7A and the resin forming the light transmissive resin layer 7B are the same, for example, the insulating resin portion 7A and the light transmissive resin layer 7B can be easily and collectively formed by forming a pattern from one curable resin layer by an imprinting method or the like.

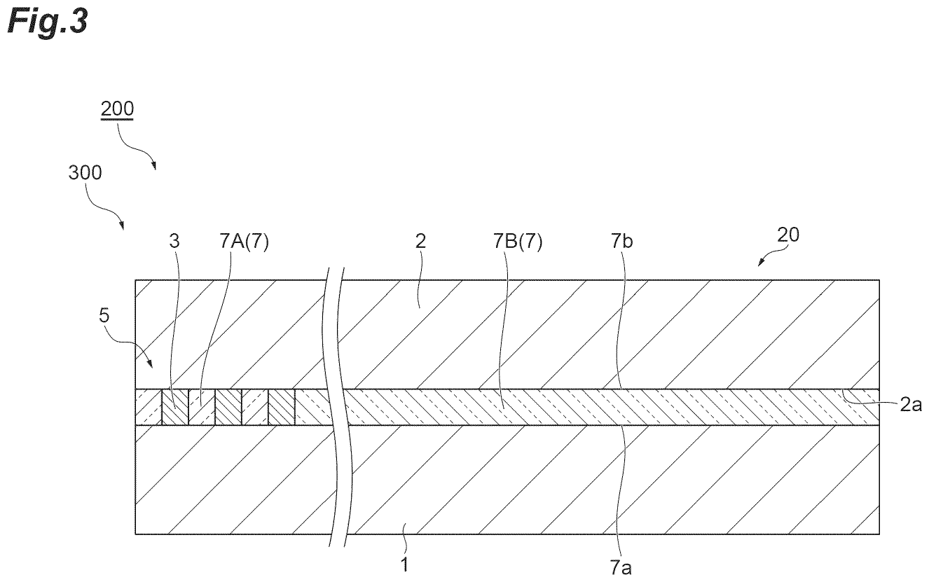

The electroconductive member 20 (wiring body 200) as illustrated in FIG. 3 may be employed. The electroconductive member 20 (wiring body 200) illustrated in FIG. 3 further includes a second adhesive layer 2 covering the first resin layer 7 and the electroconductive layer 5 from the second main surface 7b side. The second adhesive layer 2 is a layer that exerts the adhesion to another member when the wiring body 200 is adhered to the other member on the second main surface 7b side. The second adhesive layer 2 is so disposed that a main surface 2a thereof is in contact with the second main surface 7b of the first resin layer 7. However, in a case where a second resin layer 8 to be described later is provided on the second main surface 7b, the second adhesive layer 2 is in contact with the second resin layer 8. The thickness, material, and other characteristics of the second adhesive layer 2 may be similar to those of the first adhesive layer 1. However, different thicknesses or materials may be selected for the first adhesive layer 1 and the second adhesive layer 2. It is not essential that the second adhesive layer 2 covers the entire surfaces of the first resin layer 7 and the electroconductive layer 5 on the second main surface 7b side.

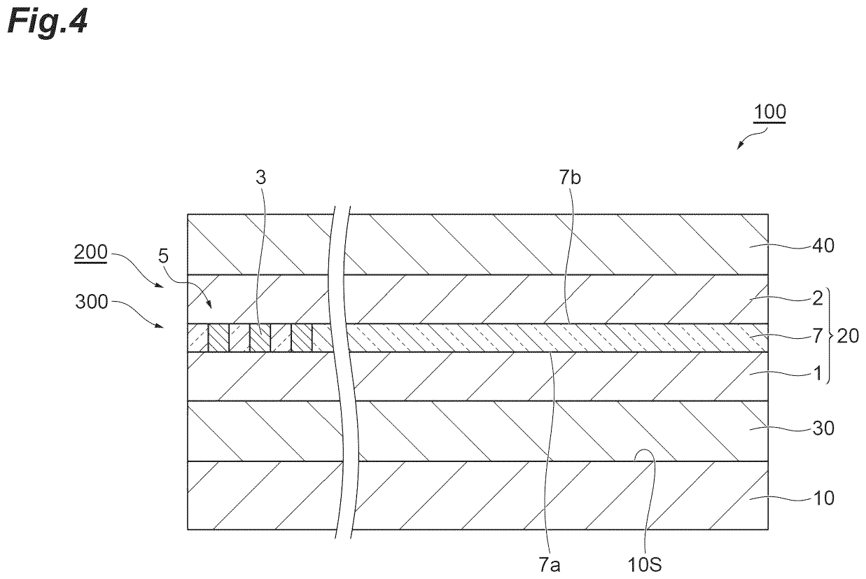

The electroconductive member exemplarily described above can be incorporated in a display device as, for example, a planar transparent antenna. The display device may be, for example, a liquid crystal display device or an organic EL display device. FIG. 4 is a cross-sectional view illustrating an embodiment of a display device in which the wiring body 200 is incorporated. A display device 100 illustrated in FIG. 4 includes an image display unit 10 having an image display region 10S, a polarizing plate 30, the electroconductive member 20, and a cover glass 40. The polarizing plate 30, the electroconductive member 20, and the cover glass 40 are laminated, in this order from the image display unit 10 side, on the image display region 10S side of the image display unit 10. The configuration of the display device 100 is not limited to the form of FIG. 4, and can be appropriately changed as necessary. For example, the polarizing plate 30 may be provided between the cover glass 40 and the electroconductive member 20. The image display unit 10 may be, for example, a liquid crystal display unit. As the polarizing plate 30 and the cover glass 40, those commonly used in a display device can be used. The polarizing plate 30 and the cover glass 40 are not necessarily provided. In FIG. 4, the cover glass 40 is provided on the second main surface 7b side, and the wiring body 200 as that illustrated in FIG. 3 is adopted. However, in a case where the cover glass 40 is omitted, the wiring body 200 illustrated in FIG. 2 may be adopted. Light for image display emitted from the image display region 10S of the image display unit 10 passes through a path having a highly uniform optical path length including the electroconductive member 20. This makes it possible to display an image with high uniformity and favorable quality with suppressed moire.

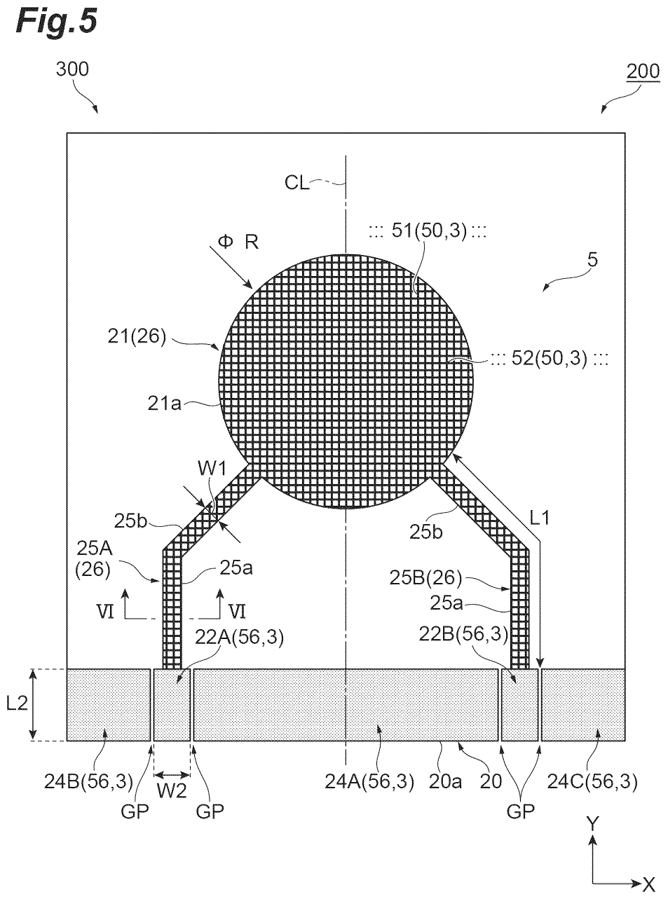

Next, a configuration of the antenna 300 including the wiring body 200 according to the embodiment of the present disclosure will be described in detail with reference to FIG. 5. The antenna 300 includes the electroconductive layer 5 described above. FIG. 5 is a plan view of the antenna 300. FIG. 5 is an enlarged view of a part of the antenna 300 including the wiring body 200. In the following description, it is assumed that XY coordinates are set with respect to a plane parallel to the main surface 1S. The Y-axis direction is a direction along the main surface 1S, and corresponds to a direction orthogonal to a side portion 20a of the electroconductive member 20 in the example illustrated in FIG. 1. The center side of the electroconductive member 20 is defined as a positive side in the Y-axis direction, and the outer peripheral side of the electroconductive member 20 is defined as a negative side in the Y-axis direction. The X-axis direction is a direction orthogonal to the Y-axis direction along the main surface 1S, and corresponds to a direction in which the side portion 20a of the electroconductive member 20 extends in the example illustrated in FIG. 1. One side in which the side portion 20a of the electroconductive member 20 extends is defined as a positive side in the X-axis direction, and the other side is defined as a negative side in the X-axis direction. In the example illustrated in FIG. 5, the antenna 300 is illustrated as a single antenna element, but the present disclosure is not limited thereto, and a plurality of antennas 300 may be arranged in the X-axis direction to form an array antenna.

The electroconductive layer 5 of the antenna 300 includes an electrode 26 including a radiation electrode 21 and feed lines 25A and 25B, terminals 22A and 22B, and ground pad portions 24A, 24B, and 24C. The antenna 300 has a linear symmetrical configuration with respect to a center line CL parallel to the Y-axis direction.

The radiation electrode 21 is a region that radiates a signal as the antenna 300. The radiation electrode 21 has a circular shape. The center of the radiation electrode 21 is located on the center line CL. The radiation electrode 21 is disposed at a position spaced apart from the side portion 20a of the electroconductive member 20 toward the positive side in the Y-axis direction. The radiation electrode 21 has a dimension of a diameter R.

The feed lines 25A and 25B are lines for feeding power to the radiation electrode 21. That is, the antenna 300 functions as a dual-polarized antenna. For example, a diagonally polarized signal in a direction in which an inclined portion 25b of the feed line 25A extends can be fed via the feed line 25A, and a diagonally polarized signal in a direction in which an inclined portion 25b of the feed line 25B extends can be fed via the feed line 25B. The feed lines 25A and 25B each have a vertical portion 25a extending perpendicular to the side portion 20a of the electroconductive member 20 and an inclined portion 25b inclined with respect to the Y-axis direction. The vertical portion 25a of the feed line 25A extends toward the positive side in the Y-axis direction from the terminal 22A formed on the side portion 20a side of the electroconductive member 20. The vertical portion 25a of the feed line 25A extends in parallel with the center line CL (that is, the Y-axis direction) at a position spaced apart from the center line CL toward the negative side in the X-axis direction.

The inclined portion 25b of the feed line 25A is inclined, from an end part of the vertical portion 25a on the positive side in the Y-axis direction, so as to approach the center line CL side (that is, the positive side in the X-axis direction) as the inclined portion 25b extends toward the positive side in the Y-axis direction. An end part of the inclined portion 25b on the positive side at the Y-axis direction is connected to an outer peripheral edge 21a of the radiation electrode 21. The feed line 25A has a constant width dimension W1 at the vertical portion 25a and the inclined portion 25b. In addition, the feed line 25A has a line length L1 that is the total dimension of the length dimension of the vertical portion 25a and the length dimension of the inclined portion 25b. Here, the width dimension W1 is a dimension in a direction orthogonal to the extending direction of the vertical portion 25a and the inclined portion 25b in the in-plane direction of the planar antenna 300, and the line length L1 is a dimension along the extending direction of the vertical portion 25a and the inclined portion 25b in the in-plane direction of the planar antenna 300.

Note that, in the example illustrated in FIG. 5, the vertical portion 25a of the feed line 25A is disposed at a position spaced apart from an end part of the radiation electrode 21 on the negative side in the X-axis direction toward the negative side in the X-axis direction. In addition, the end part of the vertical portion 25a of the feed line 25A on the positive side in the Y-axis direction (that is, the part connected to the inclined portion 25b) is disposed at a position spaced apart from an end part of the radiation electrode 21 on the negative side in the Y-axis direction toward the negative side in the Y-axis direction. However, the arrangement and shapes of the vertical portion 25a and the inclined portion 25b are not particularly limited. The feed line 25B has a structure that is linearly symmetrical to the feed line 25A with respect to the center line CL. In the present embodiment, the inclined portion 25b of the feed line 25A and the inclined portion 25b of the feed line 25B are connected to the outer peripheral edge 21a of the radiation electrode 21 such that a virtual line obtained by extending the inclined portion 25b of the feed line 25A and a virtual line obtained by extending the inclined portion 25b of the feed line 25B are orthogonal to each other. In other words, the angle formed by the virtual line obtained by extending the inclined portion 25b of the feed line 25A and the virtual line obtained by extending the inclined portion 25b of the feed line 25B is 90 degrees.

The terminals 22A and 22B are terminals connected to the feed lines 25A and 25B, respectively. The terminals 22A and 22B are connected to an external input/output terminal to supply power to the radiation electrode 21 via the feed lines 25A and 25B. The terminals 22A and 22B are disposed near the side portion 20a of the electroconductive member 20. The terminals 22A and 22B extend from end parts of the vertical portions 25a of the feed lines 25A and 25B on the negative side in the Y-axis direction to the side portion 20a toward the negative side in the Y-axis direction. The terminals 22A and 22B each extend in the Y-axis direction with a constant width dimension W2. The terminals 22A and 22B each extend in the Y-axis direction with a length dimension L2. Here, the width dimension W2 is a dimension in a direction orthogonal to the extending direction of the terminals 22A and 22B in the in-plane direction of the planar antenna 300, and the length dimension L2 is a dimension along the extending direction of the terminals 22A and 22B in the in-plane direction of the planar antenna 300.

The ground pad portions 24A, 24B, and 24C are electrically grounded regions. The ground pad portions 24A, 24B, and 24C are connected to a ground terminal (not illustrated). The ground pad portions 24A, 24B, and 24C are arranged with a gap GP with respect to the terminals 22A and 22B to thereby be insulated from the terminals 22A and 22B. The ground pad portion 24A is formed to extend in the X-axis direction along the side portion 20a in a region between the terminals 22A and 22B. The ground pad portion 24B is formed to extend in the X-axis direction along the side portion 20a in a region on the negative side in the X-axis direction of the terminal 22A. The ground pad portion 24C is formed to extend in the X-axis direction along the side portion 20a in a region on the positive side in the X-axis direction of the terminal 22B. The ground pad portions 24A, 24B, and 24C have a constant width in the Y-axis direction and extend in a band shape in the X-axis direction. The width of each of the ground pad portions 24A, 24B, and 24C is the same as the length dimension L2 of each of the terminals 22A and 22B.

As described above, the terminal 22A, which is a signal line, has a structure sandwiched between the ground pad portions 24A and 24B from both sides the terminal 22A in the X-axis direction. The terminal 22B, which is a signal line, has a structure sandwiched between the ground pad portions 24A and 24C from both sides of the terminal 22B in the X-axis direction. The terminals 22A and 22B are thus coplanar lines.

As illustrated in FIG. 5, the antenna 300 includes a mesh-like conductor pattern 50 as the conductor portion 3. Among the constituent elements of the antenna 300, the radiation electrode 21 and the feed lines 25A and 25B (electrodes) each have the mesh-like conductor pattern 50. The mesh-like conductor pattern 50 includes a plurality of first electroconductive lines 51 and a plurality of second electroconductive lines 52. The first electroconductive line 51 is the linear conductor portion 3 extending parallel to the Y-axis direction. The plurality of first electroconductive lines 51 is arranged to be spaced apart from each other in the X-axis direction. The plurality of first electroconductive lines 51 is arranged to be spaced apart at a constant pitch. The second electroconductive line 52 is the linear conductor portion 3 extending parallel to the X-axis direction. The plurality of second electroconductive lines 52 is arranged to be spaced apart from each other in the Y-axis direction. The plurality of second electroconductive lines 52 is arranged to be spaced apart at a constant pitch. The thickness of the electroconductive lines 51 and 52 is not particularly limited, and may be set to, for example, 1 to 3 μm. The pitch of the electroconductive lines 51 and 52 is not particularly limited, and may be set to, for example, 50 to 300 μm. The first electroconductive line 51 does not need to be parallel to the Y-axis direction as long as the first electroconductive line 51 extends in the Y-axis direction, and the second electroconductive line 52 does not need to be parallel to the X-axis direction as long as the second electroconductive line 52 extends in the X-axis direction.

In the present embodiment, the radiation electrode 21 and the feed lines 25A and 25B have end electroconductive lines constituting the outer peripheral edges. The radiation electrode 21 has a circular shape formed by the end electroconductive line. Note that the radiation electrode 21 having a circular shape is not limited to have a strictly perfect circular shape, and includes variations caused by manufacturing errors and the like. In addition, the end electroconductive line constituting the outer peripheral edge of the radiation electrode 21 is not limited to a curved line only, and may partially include a straight line and a wavy line portion. Further, it is not always necessary that the radiation electrode 21 and the feed lines 25A and 25B include the end electroconductive lines. In this case, it is only required that the shape formed by connecting the ends of the first electroconductive lines 51 or the second electroconductive lines 52 included in the mesh-like conductor pattern 50 is a circular shape.

The terminal 22 has a second conductor layer 56 extending in a planar shape over substantially the entire region of the terminal 22. Note that the term “terminal 22” is used to refer to both the terminal 22A and the terminal 22B without distinction. In FIG. 5, the second conductor layer 56 is formed over the entire region of the terminal 22, but the area of the second conductor layer 56 is not particularly limited. For example, the area of the second conductor layer 56 may be 95% or more of the area of the entire terminal 22. Note that the ground pad portions 24A, 24B, and 24C also include the second conductor layer 56. However, the ground pad portions 24A, 24B, and 24C may have a configuration including the mesh-like conductor pattern 50.

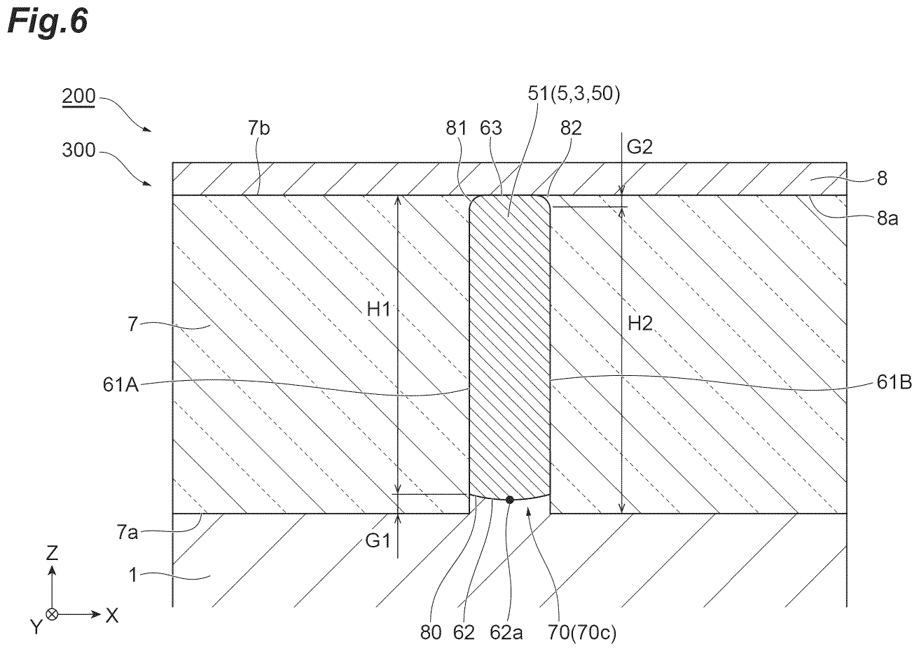

Next, a detailed cross-sectional configuration of the wiring body 200 will be described with reference to FIG. 6. FIG. 6 is a cross-sectional view taken along the line VI-VI in FIG. 5. As illustrated in FIG. 6, the wiring body 200 includes the first adhesive layer 1, the electroconductive layer 5, and the first resin layer 7. The conductor pattern 50 of the electroconductive layer 5 includes electroconductive lines 51 and 52 extending linearly in the extending direction of the first resin layer 7 (see FIG. 5). Here, the extending direction for the first electroconductive line 51 corresponds to the Y-axis direction. The extending direction for the second electroconductive line 52 corresponds to the X-axis direction. Since the first electroconductive line 51 is illustrated in FIG. 6, the Y-axis direction corresponds to the extending direction. Therefore, the orthogonal direction orthogonal to the extending direction corresponds to the X-axis direction. The height direction corresponds to the Z-axis direction. One side from the first main surface 7a toward the second main surface 7b in the height direction corresponds to the positive side in the Z-axis direction. The other side from the second main surface 7b toward the first main surface 7a in the height direction corresponds to the negative side in the Z-axis direction. However, the orientation in the height direction is not particularly limited, and the first main surface 7a may be a surface layer (upper portion). FIG. 6 illustrates a cross-sectional view of the first electroconductive line 51 when cut in the X-axis direction that is the orthogonal direction. Although FIG. 6 illustrates the configuration of the first electroconductive line 51, the second electroconductive line 52 also has the same structure, and thus description thereof is omitted.

The first electroconductive line 51 has side surfaces 61A and 61B facing each other in the X-axis direction that is the width direction. The side surface 61A is located on the negative side in the X-axis direction, and the side surface 61B is located on the positive side in the X-axis direction. The first electroconductive line 51 has an end face 62 on the other side in the height direction (negative side in the Z-axis direction). The first electroconductive line 51 has an end face 63 on one side in the height direction (positive side in the Z-axis direction).

The first resin layer 7 has a trench 70 in which the first electroconductive line 51 is disposed. In the present embodiment, the trench 70 constitutes the through hole 7c extending from the second main surface 7b on one side of the first resin layer 7 in the height direction (positive side in the Z-axis direction) to the first main surface 7a on the other side (negative side in the Z-axis direction). The trench 70, that is, the through hole 7c is formed in a mesh-like shape. The side surfaces 61A and 61B of the first electroconductive line 51 are in surface contact with the inner surface of the trench 70. The width (dimension in the X-axis direction) of the first electroconductive line 51 is constant in the height direction. However, the width of the first electroconductive line 51 may increase toward one side in the height direction (positive side in the Z-axis direction).

The first electroconductive line 51 has a first portion 80 whose height from the second main surface 7b is smaller than that of the first main surface 7a of the first resin layer 7. In FIG. 6, the height dimension of the lowest part of the heights of the first portion 80 from the second main surface 7b is indicated by “H1”. That is, the first portion 80 is located at a position on the second main surface 7b side (positive side in the Z-axis direction) with respect to the first main surface 7a. In the present embodiment, the end face 62 is curved, in the width direction (X-axis direction), such that a central portion 62a protrudes toward the negative side in the Z-axis direction. Therefore, an edge portion of the end face 62 at least in the width direction corresponds to the first portion 80. In the end face 62, the central portion 62a located on the most negative side in the Z-axis direction may correspond to the first portion 80. In this case, the entire end face 62 corresponds to the first portion. Alternatively, it is possible that the central portion 62a does not correspond to the first portion 80. In this case, a part near the central portion 62a has a height from the second main surface 7b greater than or equal to that of the first main surface 7a of the first resin layer 7. The first adhesive layer 1 enters the through hole 7c and is in contact with the first portion 80 of the first electroconductive line 51 in the through hole 7c. The first adhesive layer 1 contacts substantially the entire region of the end face 62. The shape of the end face 62 is not limited to the above-described shape, and is not limited to the curved shape with the central portion 62a protruding.

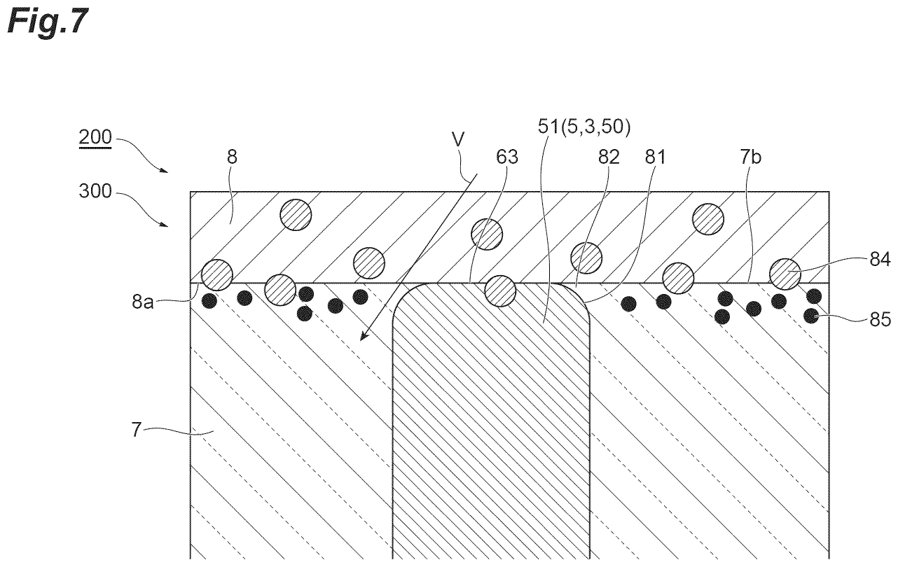

The first electroconductive line 51 has a second portion 81 whose height from the first main surface 7a is smaller than that of the second main surface 7b of the first resin layer 7. In FIG. 6, the height dimension of the lowest part of the heights of the second portion 81 from the first main surface 7a is indicated by “H2”. That is, the second portion 81 is located at a position on the first main surface 7a side (negative side in the Z-axis direction) with respect to the second main surface 7b. In the present embodiment, in the width direction (X-axis direction), the end face 63 has such a shape that the edge portions extend toward the negative side in the Z-axis direction as the edge portions extend outward in the width direction. A region near the central portion of the end face 63 in the width direction is located at the same height as that of the second main surface 7b. The first resin layer 7 has a cover portion 82 that covers the second portion 81 from the second main surface 7b side (see also FIG. 7). The cover portion 82 extends toward the central portion side in the width direction along the curved shape of the second portion 81. Therefore, the end face 63 is covered with the second main surface 7b at a part of the edge portions on both sides of the end face 63 in the width direction, and a part of the end face 63 on the central side is exposed from the second main surface 7b.

The difference in height between the second main surface 7b and the second portion 81 is smaller than the difference in height between the first main surface 7a and the first portion 80. In the case of comparing the two, comparison is made between portions of the first portion 80 and the second portion 81 that are farthest away from the main surfaces 7a and 7b, respectively. The difference in height between the first main surface 7a and the first portion 80 at the lowest position is denoted by “G1”. The difference in height between the second main surface 7b and the second portion 81 at the lowest position is denoted by “G2”. At this time, “G1>G2” holds.

The wiring body 200 further includes a second resin layer 8 covering the first resin layer 7 and the electroconductive layer 5 from the second main surface 7b side. The second resin layer 8 is a layer called a hard coat layer. The main surface 8a of the second resin layer 8 is provided so as to be in contact with the second main surface 7b of the first resin layer 7 and the end face 63 of the first electroconductive line 51. The second resin layer 8 may be a layer containing a resin and an inorganic filler. Examples of the resin constituting the second resin layer 8 include an acrylic resin. Examples of the inorganic filler include silica. The thickness of the second resin layer 8 may be, for example, greater than or equal to 5 nm, greater than or equal to 100 nm, or greater than or equal to 200 nm, and may be less than or equal to 10 μm, less than or equal to 5 μm, or less than or equal to 2 μm.

FIG. 7 is an enlarged cross-sectional view illustrating a configuration in the vicinity of the end face 63 of the first electroconductive line 51 illustrated in FIG. 6. A configuration in the vicinity of a boundary between the second resin layer 8 and the first resin layer 7 will be described with reference to FIG. 7. The second resin layer 8 contains inorganic particles 84. Metal fine particles 85 are dispersed on the interface side of the first resin layer 7 with the second resin layer 8.

The inorganic particles 84 are dispersed in the second resin layer 8. In addition, some of the inorganic particles 84 may be present beyond the main surface 8a of the second resin layer 8 and be in contact with the first resin layer 7. Examples of the inorganic particles 84 include silica, alumina, titania, tantalum oxide, zirconia, silicon nitride, barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, barium silicate, boron nitride, calcium carbonate, barium sulfate, calcium sulfate, zinc oxide, magnesium titanate, hydrotalcite, mica, calcined kaolin, and carbon. The inorganic particles 84 may be one kind alone or a combination of two or more kinds.

The shape of the inorganic particles 84 is not particularly limited, and may be, for example, spherical, ellipsoidal, polyhedral, plate-like, scale-like, columnar, or the like.

The average particle diameter of the inorganic particles 84 may be, for example, greater than or equal to 10 nm, greater than or equal to 15 nm, or greater than or equal to 20 nm, and may be less than or equal to 400 nm, less than or equal to 300 nm, or less than or equal to 200 nm. The average particle diameter of the inorganic particles 84 is calculated by observing a cross section of the wiring body 200 along the thickness direction with a TEM, measuring the maximum length of each of the inorganic particles 84 present in a range of 1.5 μm in the extending direction of the wiring body 200 in a TEM image of the cross section, and averaging the maximum lengths.

The metal fine particles 85 may be one or more kinds of inorganic particles selected from Pd, Cu, Ni, Co, Au, Ag, Pd, Rh, Pt, In, and Sn, or may include Pd. The metal fine particles 85 may be one kind alone or a combination of two or more kinds of inorganic particles.

The shape of the metal fine particles 85 is not particularly limited, and may be, for example, spherical, ellipsoidal, polyhedral, plate-like, scale-like, columnar, or the like.

The average particle diameter of the metal fine particles 85 may be 10 nm or less, 8 nm or less, or 5 nm or less from the viewpoint of excellent transparency of the electroconductive member 20. The average particle diameter of the metal fine particles 85 may be, for example, 0.1 nm or more, 0.5 nm or more, or 1 nm or more. The average particle diameter of the metal fine particles 85 is calculated by observing the cross section of the wiring body 200 along the thickness direction with a TEM, measuring the maximum length of each of the metal fine particles 85 present in a range of 1.5 μm in the extending direction of the wiring body 200 in a TEM image of the cross section, and averaging the maximum lengths.

The average particle diameter of the metal fine particles 85 may be smaller than the average particle diameter of the inorganic particles 84. The ratio of the average particle diameter of the metal fine particles 85 to the average particle diameter of the inorganic particles 84 (average particle diameter of the metal fine particles 85/average particle diameter of the inorganic particles 84) may be 0.3 or less or 0.1 or less, or may be 0.01 or more, 0.02 or more, or 0.05 or more.

The state in which the inorganic particles 84 are dispersed in the second resin layer 8 is the following state: in a case where the cross section of the wiring body 200 along the thickness direction is observed with a TEM and a pattern of squares with 500 μm is set, at least one particle is present in each square. The state in which the metal fine particles 85 are dispersed on the interface side of the first resin layer 7 with the second resin layer 8 is a state in which the metal fine particles 85 are dispersed within a range of 100 μm of the first resin layer 7 in the thickness direction at the boundary between the main surfaces 7b and 8a. The state in which the metal fine particles 85 are dispersed within the range is the following state: in a case where the cross section of the wiring body 200 along the thickness direction is observed with a TEM and a pattern of squares with 100 nm is set, at least one particle is present in each square.

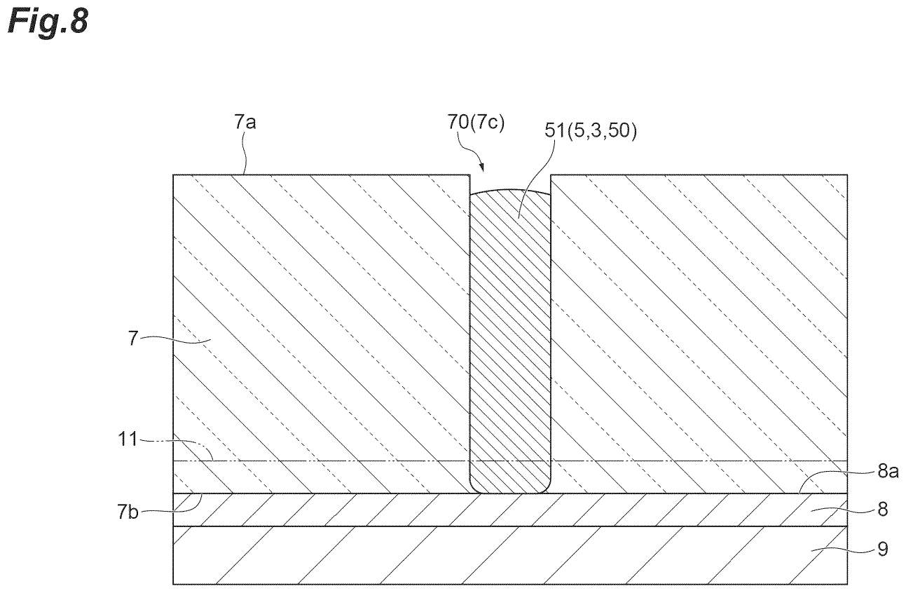

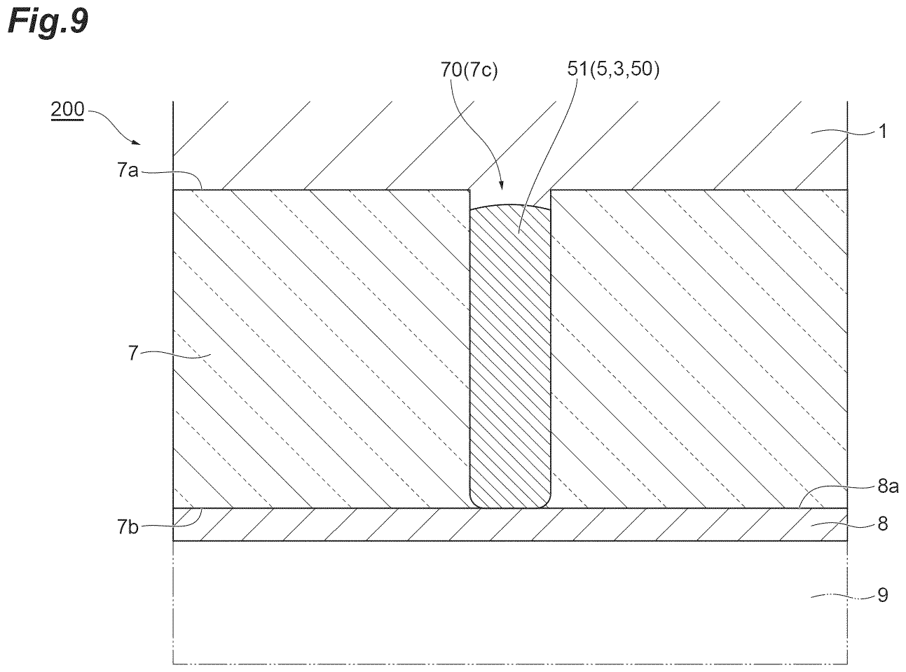

Next, a method of manufacturing the wiring body 200 will be described with reference to FIGS. 8 and 9. FIGS. 8 and 9 are schematic cross-sectional views illustrating a method of manufacturing the wiring body 200. First, as illustrated in FIG. 8, a material in which the second resin layer 8 is formed on an upper surface of a substrate 9 is prepared. In FIGS. 8 and 9, unlike FIGS. 2 to 4, 6, and 7, the first resin layer 7 is so disposed that the first main surface 7a is a surface on the upper side and the second main surface 7b is a surface on the lower side.

As the substrate 9, for example, cycloolefin polymer (COP), polyethylene terephthalate (PET), polycarbonate (PC) or the like may be employed, and the substrate 9 is not particularly limited thereto. The second resin layer 8 contains the inorganic particles 84 (see FIG. 7). A third resin layer 11 indicated by a virtual line is laminated on the main surface 8a of the second resin layer 8. The third resin layer 11 contains the metal fine particles 85 (see FIG. 7). The third resin layer 11 is removed using an ashing process or the like. At this time, the resin component of the third resin layer 11 is removed, but the metal fine particles 85 present in the third resin layer 11 are not removed, and remain on the main surface 8a side of the second resin layer 8. The first resin layer 7 is formed by applying a resin composition containing the resin component forming the first resin layer 7 onto the main surface 8a on which the metal fine particles 85 are deposited. The mesh-like through hole 7c is formed in the first resin layer 7. The electroconductive layer 5 is formed by performing electroless plating and/or electrolytic plating on the member provided with the mesh-like through hole 7c (member including the substrate 9, the metal fine particles 85, the second resin layer 8, and the first resin layer 7).

Next, as illustrated in FIG. 9, the substrate 9 is removed. The method of removing the substrate 9 is not particularly limited, and a method of forming the first adhesive layer 1 on the first main surface 7a side of the first resin layer 7 and then peeling the substrate 9 may be adopted. Thus, the wiring body 200 is completed.

Next, functions and effects of the wiring body 200 and the display device 100 according to the present embodiment will be described.

The wiring body 200 according to the present embodiment includes the first resin layer 7 having the first main surface 7a and the second main surface 7b and having the through hole 7c passing from the first main surface 7a to the second main surface 7b, the electroconductive layer 5 disposed in the through hole 7c, and the first adhesive layer 1 covering the first resin layer 7 and the electroconductive layer 5 from the first main surface 7a side.

The wiring body 200 includes the first resin layer 7 that has the first main surface 7a and the second main surface 7b and has the through hole 7c passing from the first main surface 7a to the second main surface 7b. The electroconductive layer 5 is disposed in the through hole 7c of the first resin layer 7. Accordingly, the shape of the electroconductive layer 5 can be maintained by the first resin layer 7 without supporting the electroconductive layer 5 with a substrate or the like. The wiring body 200 includes the first adhesive layer 1 covering the first resin layer 7 and the electroconductive layer 5 from the first main surface 7a side. Accordingly, the wiring body 200 can be adhered to another member by the first adhesive layer 1 without interposing a substrate or the like therebetween. This can omit the thickness of the substrate or the like. As described above, the thickness of the wiring body 200 can be reduced while the shape of the electroconductive layer 5 is maintained.

The electroconductive layer 5 has the first portion 80 whose height from the second main surface 7b is smaller than that of the first main surface 7a of the first resin layer 7, and the first adhesive layer 1 may be in contact with the first portion 80 of the electroconductive layer 5 in the through hole 7c. In this case, the adhesion between the first adhesive layer 1 and the first resin layer 7 as well as the electroconductive layer 5 can be increased by virtue of an anchor effect of the first adhesive layer 1 entering the through hole 7c.

The wiring body 200 may further include the second resin layer 8 covering the first resin layer 7 and the electroconductive layer 5 from the second main surface 7b side. In this case, the second resin layer 8 can protect the electroconductive layer 5 from the second main surface 7b side.

The second resin layer 8 may contain the inorganic particles 84. In this case, weather proof and rust resistance of the wiring body 200 are improved.

The metal fine particles 85 may be dispersed on the interface side of the first resin layer 7 with the second resin layer 8. In this case, as viewed from the second main surface 7b side, the metal fine particles 85 are present around the interface between the electroconductive layer 5 and the first resin layer 7. Therefore, the color of the metal fine particles 85 is adapted to the color of the electroconductive layer 5. This prevents an increase in visibility of the interface between the electroconductive layer 5 and the first resin layer 7.

The wiring body 200 may further include the second adhesive layer 2 covering the first resin layer 7 and the electroconductive layer 5 from the second main surface 7b side. In this case, the wiring body 200 can be adhered to other members on both sides of the first main surface 7a and the second main surface 7b; therefore, the wiring body 200 can be applied to a device having a laminated structure.

The electroconductive layer 5 may have the second portion 81 whose height from the first main surface 7a is smaller than that of the second main surface 7b of the first resin layer 7. In this case, as viewed from the second main surface 7b side, the second portion 81 is disposed at a position recessed from the second main surface 7b, and is difficult to see. This enhances the invisibility of the electroconductive layer 5. Since the second portion 81 is provided at the edge portions of the end face 63 in the width direction, it can be made invisible from the line of sight V in the oblique direction from the second main surface 7b side (see FIG. 7).

The difference in height between the second main surface 7b and the second portion 81 may be smaller than the difference in height between the first main surface 7a and the first portion 80. In this case, it is possible to increase the invisibility of the electroconductive layer 5 while the conductor volume of the electroconductive layer 5 is achieved.

The first resin layer 7 may have the cover portion 82 that covers the second portion 81. This increases the adhesion between the first resin layer 7 and the electroconductive layer 5.

The electroconductive layer 5 may be disposed in the through hole 7c formed in a mesh-like shape. In this case, the mesh-like electroconductive layer 5 can be formed.

A display device according to an aspect of the present disclosure includes the wiring body.

According to the display device 100, functions and effects similar to those of the wiring body 200 described above can be achieved.

The present disclosure is not limited to the embodiment described above.

In the embodiment described above, the example in which the wiring body 200 is applied to the display device 100 has been exemplified, but there is no particular limit to what the wiring body 200 is applied. For example, the wiring body 200 is applicable to a window glass or the like. For example, in a case where the second adhesive layer 2 is not provided as illustrated in FIG. 2, the first adhesive layer 1 may be adhered to a glass part to form a transparent antenna.

In the embodiment described above, the case where the wiring body 200 includes the second resin layer 8 has been exemplified. However, the second resin layer 8 may be omitted. Accordingly, the inorganic particles 84 and the metal fine particles 85 may also be omitted.

### Embodiment 1

A wiring body including:
a first resin layer having a first main surface and a second main surface and having a through hole passing from the first main surface to the second main surface;
an electroconductive layer disposed in the through hole; and
a first adhesive layer covering the first resin layer and the electroconductive layer from the first main surface side.

### Embodiment 2

The wiring body according to embodiment 1, in which
the electroconductive layer has a first portion whose height from the second main surface is smaller than a height of the first main surface of the first resin layer, and
the first adhesive layer is in contact with the first portion of the electroconductive layer in the through hole.

### Embodiment 3

The wiring body according to embodiment 1 or 2, further including a second resin layer covering the first resin layer and the electroconductive layer from the second main surface side.

### Embodiment 4

The wiring body according to embodiment 3, in which the second resin layer contains inorganic particles.

### Embodiment 5

The wiring body according to embodiment 3 or 4, in which metal fine particles are dispersed on an interface side of the first resin layer with the second resin layer.

### Embodiment 6

The wiring body according to any one of embodiments 1 to 5, further including a second adhesive layer covering the first resin layer and the electroconductive layer from the second main surface side.

### Embodiment 7

The wiring body according to embodiment 2, in which the electroconductive layer has a second portion whose height from the first main surface is smaller than a height of the second main surface of the first resin layer.

### Embodiment 8

The wiring body according to embodiment 7, in which a difference in height between the second main surface and the second portion is smaller than a difference in height between the first main surface and the first portion.

### Embodiment 9

The wiring body according to embodiment 7 or 8, in which the first resin layer includes a cover portion covering the second portion from the second main surface side.

### Embodiment 10

The wiring body according to any one of embodiments 1 to 9, in which the electroconductive layer is disposed in the through hole formed in a mesh-like shape.

### Embodiment 11

A display device including the wiring body according to any one of embodiments 1 to 10.

### REFERENCE SIGNS LIST

1 First adhesive layer
2 Second adhesive layer
5 Electroconductive layer
7 First resin layer
7a First main surface
7b Second main surface
7c Through hole
8 Second resin layer
80 First portion
81 Second portion
82 Cover portion
84 Inorganic particles
85 Metal fine particles
100 Display device
200 Wiring body

What is claimed is:

1. A wiring body comprising:
a first resin layer having a first main surface and a second main surface and having a through hole passing from the first main surface to the second main surface;
an electroconductive layer disposed in the through hole; and
a first adhesive layer covering the first resin layer and the electroconductive layer from the first main surface side.

2. The wiring body according to claim 1, wherein
the electroconductive layer has a first portion whose height from the second main surface is smaller than a height of the first main surface of the first resin layer, and
the first adhesive layer is in contact with the first portion of the electroconductive layer in the through hole.

3. The wiring body according to claim 1, further comprising a second resin layer covering the first resin layer and the electroconductive layer from the second main surface side.

4. The wiring body according to claim 3, wherein the second resin layer contains inorganic particles.

5. The wiring body according to claim 3, wherein metal fine particles are dispersed on an interface side of the first resin layer with the second resin layer.

6. The wiring body according to claim 1, further comprising a second adhesive layer covering the first resin layer and the electroconductive layer from the second main surface side.

7. The wiring body according to claim 2, wherein the electroconductive layer has a second portion whose height from the first main surface is smaller than a height of the second main surface of the first resin layer.

8. The wiring body according to claim 7, wherein a difference in height between the second main surface and the second portion is smaller than a difference in height between the first main surface and the first portion.

9. The wiring body according to claim 7, wherein the first resin layer includes a cover portion covering the second portion from the second main surface side.

10. The wiring body according to claim 1, wherein the electroconductive layer is disposed in the through hole formed in a mesh-like shape.

11. A display device including the wiring body according to claim 1.
